(19) United States
(12) Patent Application Publication
(10) Pub. No.: US 2018/0315644 A1
(43) Pub. Date: Nov. 1, 2018

(54) METHOD OF ELIMINATING FAULTS IN A SEMICONDUCTOR FILM COMPRISING THE FORMATION OF A HYDROGEN TRAPPING LAYER

(71) Applicant: COMMISSARIAT A L'ENERGIE ATOMIQUE ET AUX ENERGIES ALTERNATIVES, Paris (FR)

(72) Inventors: Aurelie TAUZIN, Saint-Egreve (FR); Emmanuelle LAGOUTTE, St Marcellin (FR); Frederic MAZEN, Saint-Egreve (FR); Flavia PIEGAS LUCE, Grenoble (FR); Shay REBOH, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 15/771,557

(22) PCT Filed: Oct. 28, 2016
(86) PCT No.: PCT/EP2016/076033

§ 371 Date: Apr. 27, 2018

(30) Foreign Application Priority Data
Oct. 30, 2015 (FR) 15 60418

(51) Int. Cl. H01L 21/762

(52) U.S. Cl. CPC H01L 21/76254

(57) ABSTRACT

The invention relates to a method of treating a thin film transferred from a donor substrate to a receiver substrate by fracture at the level of a zone of the donor substrate which is made fragile by hydrogen ion implantation. The method includes a step of thinning the transferred thin film so as to eliminate a region of residual defects induced by the hydrogen ion implantation. The method also includes, directly after the fracture and before the step of thinning of the transferred thin film, a step of forming a hydrogen trapping layer in the region of residual defects of the transferred thin film. A thermal processing may be implemented after formation of the hydrogen trapping layer and before thinning of the thin film.

### TECHNICAL FIELD

The field of the invention is that of the manufacture of semiconductor substrates. The invention relates more particularly to the finishing treatments applied to a thin film transferred onto a receiving substrate in accordance with the Smart Cut™ method, the purpose of said treatment being to eliminate a region of residual defects caused by the ion implantation used in this method.

### PRIOR ART

Smart Cut™ technology allows the detachment of a thin film from a donor substrate and transfer thereof to a receiving substrate by implementing the following steps:
ion bombardment of a face of the donor substrate with gaseous species (hydrogen and/or rare gases) in a sufficient concentration to create a layer of buried microcavities in the donor substrate, at a depth that depends mainly on the implantation energy (for a given substrate and implanted species);
putting this face of the donor substrate in intimate contact with a receiving substrate, for example by molecular adhesion; and
fracture at the buried microcavity layer, by applying a heat treatment and/or a mechanical stress.

After fracture, there are obtained firstly a composite substrate consisting of a thin film (the thickness of which corresponds to the depth of the buried microcavity layer in the donor substrate) attached to the receiving substrate, and secondly the residue of the donor substrate.

Finishing treatments on the composite substrate are subsequently implemented conventionally. These treatments typically comprise the following steps:
mechanochemical polishing that makes it possible to finely adjust the thickness of the thin film transferred while eliminating defects and/or residual gaseous species caused by the implantation and situated in the vicinity of the fractured surface. This polishing moreover makes it possible to recover excellent surface quality, typically smoothing to the atomic scale;
heat treatment, generally at high temperature (in the range 200° C. to 1100° C.), which makes it possible both to consolidate the bonding interface (in particular in the case of molecular adhesion) and to eliminate any defects and/or residual gaseous species present in the volume of the thin film transferred;
cleaning that aims to eliminate the metal particles and contamination caused by the previous steps. Some cleaning steps may also be specific to the application, for example in order to carry out surface passivation making it possible to execute a subsequent epitaxy operation.

In the case of certain donor substrates implanted with hydrogen, in particular Si, Ge or GaN ones, the residual-defect region after fracture is situated in the immediate vicinity of the surface, typically to a depth of less than 100 nm under the fractured surface. Moreover, heat treatment causes an exodiffusion of the residual hydrogen, mainly through the fractured surface, which is thus eliminated from the transferred film. The finishing treatments then do not cause the formation of new faults.

In other cases, nevertheless, for example for InP, GaAs or alloy {In, P, Ga, As} films, a large and very extensive quantity of residual hydrogen is observed after fracture. This so-called “hydrogen-rich” zone extends from the fractured surface to a depth that may correspond in certain cases to 60% or even 90% of the thickness of the transferred film. The hydrogen concentration in this hydrogen-rich zone may be greater than 2.10²⁰ ions/cm³.

Because of the thickness of this hydrogen-rich zone, it is not always possible to completely eliminate it by thinning the transferred film (for example by polishing), the remaining thickness being effectively too small and/or unsuitable for the applications sought. However, the residual hydrogen present in the films after fracture may, during subsequent consolidation annealing of the bonding interface at a temperature above 300° C., diffuse and come to be trapped at the bonding interface. The presence of hydrogen at the bonding interface may then cause microscopic detachments between the thin film transferred and the receiving substrate that are sufficiently great to cause the formation of blisters on the surface of the films transferred.

In FIGS. 1a to 1b, which illustrate this problem, FIG. 1a shows more particularly the hydrogen [H] concentration according to the depth Pf in a transferred film of InP 780 nm thick for various cases. FIG. 1a shows more precisely profiles obtained by secondary ionisation mass spectrometry that makes it possible to measure the quantity of interstitial hydrogen (“diluted” in the crystalline mesh of the substrate) but not the molecular hydrogen (in H2 gaseous form).

Curve A thus illustrates the hydrogen concentration, measured directly after the fracture. The surface S of the film is situated at the depth “0 nm” and the hydrogen-rich zone corresponds roughly to 70% of the thickness of the film.

Curve B for its part represents the concentration of hydrogen after the performance of finishing treatments comprising a mechanochemical polishing to a thickness of 400 nm in order to obtain the required final thickness of InP of 380 nm (the surface of the thin film is thus situated at the depth “400 nm” in FIG. 1a) and annealing at 600° C. carried out to consolidate the bonding.

The hatched zone QHr represents schematically the quantity of residual hydrogen eliminated from the transferred film by the annealing at 600° C. It is found that this residual hydrogen does not completely exodiffuse through the free surface of the film, but that at least some comes to be trapped at the bonding interface Ic.

This presence of hydrogen at the bonding interface, in gaseous form, leads to the formation of blisters on the surface of the transferred film, as attested to by the microphotograph reproduced in FIG. 1b.

### DISCLOSURE OF THE INVENTION

The objective of the invention is to improve the quality of the thin films obtained by transfer in accordance with the Smart Cut™ method, and aims more particularly to avoid the formation of blisters on the surface of such thin films resulting from a large and extensive residual quantity of hydrogen after fracture.

To this end, the invention proposes a method of treating a thin film transferred from a donor substrate to a receiver substrate by fracture at the level of a zone of the donor substrate which is made fragile by hydrogen ion implantation, the method comprising a step of thinning the transferred thin film so as to eliminate a region of residual defects, and being characterised in that it comprises, directly after the fracture and before the step of thinning of the transferred thin film, a step of forming a hydrogen trapping layer in the region of residual defects of the transferred thin film, the thinning extending at least from the surface of the thin film to the hydrogen trapping layer.

Certain preferred but non-limitative aspects of this method are as follows:
the formation of the hydrogen trapping layer comprises the introduction of a substance into the transferred thin film chosen for example from Li, B, C, N, F, Si, P and 5;
the introduction of the hydrogen trapping substance into the transferred thin film is carried out by ion implantation;
it comprises, between the step of formation of the hydrogen trapping layer and the step of thinning the transferred thin film, a heat treatment step applied to the thin film transferred onto the receiving substrate;
the heat treatment step is carried out at a temperature of between 300° C. and 700° C.;
the heat treatment step is carried out in an atmosphere devoid of hydrogen;
the step of thinning the transferred thin film comprises a removal of the hydrogen trapping layer;
the step of thinning the transferred thin film comprises mechanochemical polishing;
the transferred film is produced from one or more materials chosen from InP or GaAs or an alloy based on the following materials In, P, Ga, As.

### BRIEF DESCRIPTION OF THE DRAWINGS

Other aspects, aims, advantages and features of the invention will emerge more clearly from a reading of the following detailed description of preferred embodiments thereof, given by way of non-limitative example, and made with reference to the accompanying drawings, in which, apart from FIGS. 1a, 1b already discussed previously:

FIG. 2a-2d are diagrams illustrating the various steps of a possible embodiment of the method according to the invention;

FIG. 3 is a diagram comparing the hydrogen concentration in the depth of a transferred film according to various treatments applied after fracture,

FIGS. 4a and 4b are microphotographs illustrating the surface state of a transferred thin film depending on whether or not the invention is implemented;

FIG. 5 is another diagram comparing the hydrogen concentration in the depth of a transferred film according to various treatments applied after fracture.

### DETAILED DISCLOSURE OF PARTICULAR EMBODIMENTS

The subject matter of the invention is a method for the finishing treatment of a thin film transferred onto a receiver substrate in accordance with the Smart Cut™ method by fracture at a zone of a donor substrate made fragile by hydrogen ion implantation.

The method according to the invention thus follows operations consisting of forming, by hydrogen ion implantation, a weakened zone in the donor substrate, putting the donor substrate and the receiver substrate in intimate contact, for example by direct bonding (i.e. without a bonding layer), and fracturing the donor substrate at the weakened zone, for example by applying a heat treatment accompanied or not by mechanical stresses.

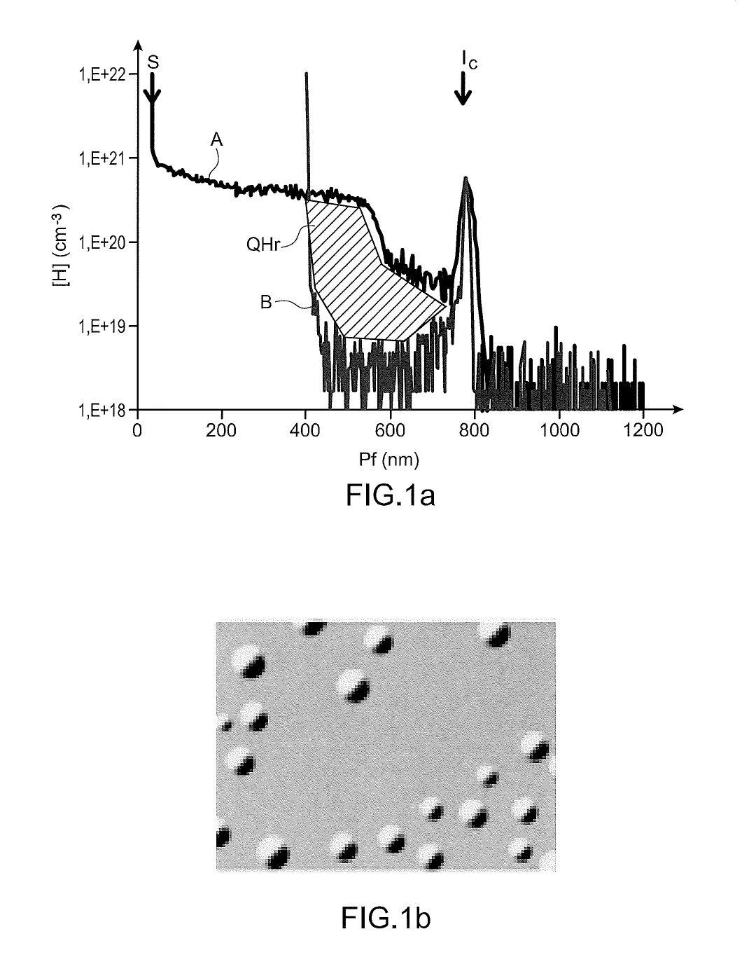

With reference to FIG. 2a, immediately after fracture, the transferred thin film 1 has a region 11 of residual defects caused by the hydrogen ion implantation (a region generally referred to as “hydrogen rich”), that extends at a depth from the fractured surface. The transferred thin film 1 thus comprises the residual-defect region 11 on a region 12, devoid overall of such structure defects, which extends between the structural-defect region 11 and the receiver substrate 2.

Without this being limitative, the invention advantageously finds an application to the finishing treatments of composite substrates comprising a superficial thin film of a material X transferred by Smart Cut™ onto a receiver substrate of a material Y, by means of hydrogen implantation, direct bonding (i.e. without bonding layer) and a heat fracture treatment (assisted or not by mechanical stresses). The materials X and Y are for example InP or GaAs or an alloy based on {In, P, Ga, As} or a stack of these materials.

The method according to the invention comprises a step that consists of forming, in the residual-defect region 11, a hydrogen trapping layer 13. This trapping layer will in particular make it possible to prevent the hydrogen present being concentrated at the bonding interface. The creation of this trapping layer is implemented immediately after fracture of the donor substrate in that no thermal budget that would cause the migration of the hydrogen to the bonding interface is applied between these two steps.

This step of forming the hydrogen trapping layer 13 is shown in FIG. 2b. It comprises the introduction of a substance in the transferred thin film, for example by means of an ion implantation Bi of said surface through the surface of the transferred thin film 1. Said substance is introduced in a sufficient concentration to create a trapping layer in the hydrogen-rich region 11 (this region even being able to get amorphised for high implanted concentrations). The trapping capacity of this layer 13 may result from the trapping capacity of the implanted substance itself and/or from the defects related to the implantation of this substance. It may be accompanied, in particular when this trapping layer extends from the fractured surface, by a capacity to facilitate the exodiffusion of the hydrogen to this fractured surface. The trapping mainly takes place at the concentration peak of the substance thus introduced. In the case of an ion implantation Bi, the position of this peak depends mainly on the implantation energy (for a given implanted material and implanted species).

The hydrogen trapping layer 13 is formed in the region of residual defects 11 as shown in FIG. 2b, preferably in the vicinity of the fractured surface, in order to recover, as will be seen, a useful zone devoid of greater defects.

The hydrogen trapping substances that can be introduced by ion implantation are for example ions from among Li, B, C, N, F, Si, P and S, which have a strong affinity with hydrogen. The hydrogen trapping substances are introduced at high doses in the transferred thin film, typically between 10¹³ and 10¹⁶ ions/cm².

The invention is not limited to the formation of a single hydrogen trapping layer, but also covers the formation of a plurality of hydrogen trapping layers, for example by having recourse to a plurality of implantations of one or more hydrogen trapping substances.

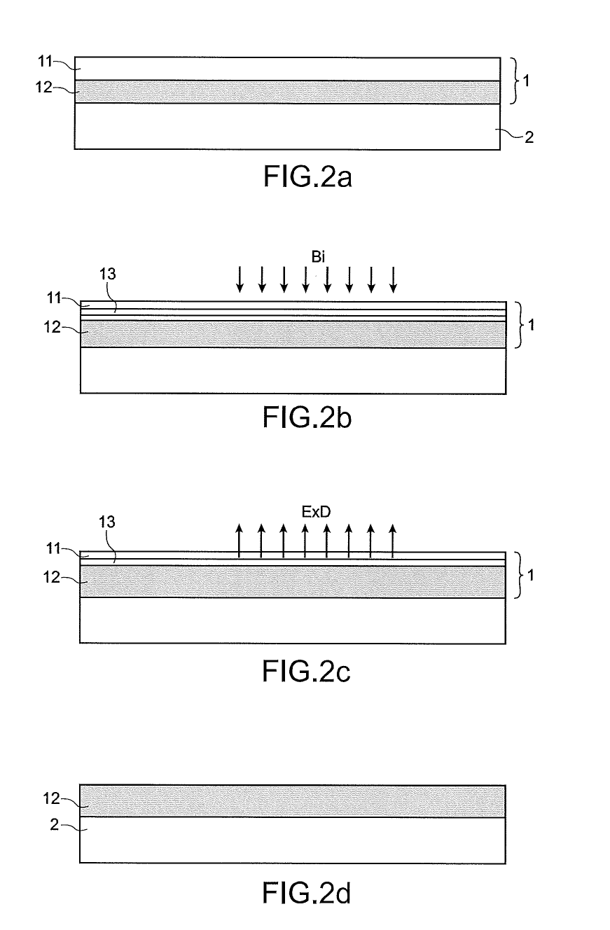

The effect of the hydrogen trapping layer has been observed during experiments, of which FIG. 3 gives an idea. As with FIG. 1a, FIG. 3 shows the hydrogen [H] concentration as a function of the depth Pf in a transferred film of InP 780 nm thick for various cases. The curve C thus illustrates the hydrogen concentration, measured directly after the fracture, while the curve D shows the hydrogen concentration after formation of the hydrogen trapping layer by implantation of P at a dose of 5×10¹⁵ P⁺/cm² and an energy of 230 keV (the peak Rp is then situated at 235 nm from the surface). From a comparison of these two curves, a hydrogen trapping effect is noted at the concentration peak Rp of the implanted phosphorus. This trapping is accompanied by an increase in the size of the useful region 12 devoid of structural defects (around 200 nm as against 150 nm without production of the trapping layer).

It is then possible to proceed with a step of thinning the transferred thin film 1 in order to preserve only this region 12 free from defects.

As shown in FIG. 2c, the method according to the invention advantageously comprises, between the step of forming the hydrogen trapping layer 13 and the step of thinning the transferred thin film 1, a heat treatment step applied to the thin film 1 transferred onto the receiver substrate 2. This step facilitates diffusion of the residual hydrogen after fracture through the fracture surface (exodiffusion represented by the reference ExD in FIG. 2c) and/or to the trapping layer (and the implantation peak), thus preventing its diffusing to the bonding interface.

This heat treatment step can be carried out at a temperature of between 300° C. and 700° C. Its duration may be between a few seconds and a few hours. It is preferably carried out in a controlled atmosphere devoid of any hydrogen (for example under vacuum, N₂ or Ar).

The curve E in FIG. 3 illustrates the hydrogen concentration after implementation of such heat treatment at 400° C. for one hour. Trapping of the hydrogen is observed at the concentration peak Rp of implanted phosphorus, as well as a significant reduction in the residual quantity of hydrogen. The size of the useful region 12 devoid of defects is thus significantly increased (around 400 nm as against 200 nm without heat treatment): it now extends from the bonding interface as far as the trapping layer. By way of comparison, the curve F in FIG. 3 illustrates the concentration of hydrogen after implementation of a heat treatment of 400° C. for one hour, directly after fracture, without formation of a hydrogen trapping layer. On the curve E, the hydrogen trapping at the concentration peak of P means that the quantity trapped cannot lead to the formation of bubbles at the bonding interface.

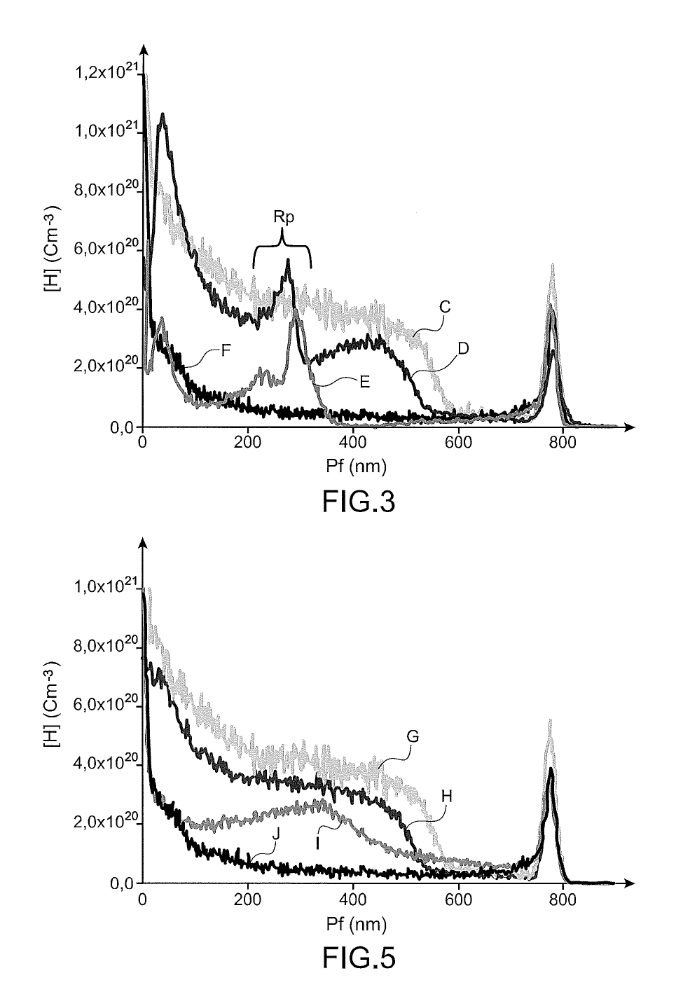

FIGS. 4a and 4b also reproduce surface microphotographs of the transferred thin film corresponding respectively to the curves F and E in FIG. 3. The quantity of defects (blisters) formed in the context of the invention (FIG. 4b) is thus much less than the reference (FIG. 4a), which indicates that the hydrogen is indeed trapped in the trapping layer and/or exodiffused from the thin film, rather than diffused to the bonding interface.

The method according to the invention also comprises, with reference to FIG. 2d, after formation of the hydrogen trapping layer and optional application of a heat treatment, thinning of the transferred thin film 1 in order to keep only the region 12 free from defects. Advantageously, the thinning thus takes place from the fractured surface until the trapping layer 13 is completely eliminated. It may of course be continued so as to reach a desired thickness for the region 12 free from defects, and is preferably stopped before the initial post-fracture interface between the regions 11 and 12. This thinning is typically achieved by polishing or etching.

The thinning may be followed by the application of a new heat treatment, for example at a temperature of between 300° and 700° C. This new heat treatment helps to reinforce the bonding interface and to eliminate defects caused by implantation.

Two example embodiments of the invention are as follows.

### EXAMPLE 1

The donor substrate is an InP substrate (100) with a diameter of 100 mm, n-doped with sulphur atoms in a concentration of 1.10¹⁷ to 1.10¹⁹/cm³. This donor substrate is implanted with hydrogen ions at an energy of 100 keV, a dose of 6.5.10¹⁶/cm² and a temperature of 140° C. The implanted surface is bonded to a GaAs substrate with a diameter of 100 mm by direct bonding, after chemical cleaning and putting the surfaces in intimate contact. Fracture is caused by annealing at 275° C. comprising ramps and level steps to a total duration of 8 hours. The film of InP thus transferred onto the GaAs substrate has a thickness of 780 nm. The hydrogen-rich zone of this film extends from the surface to a depth of 550 nm. The quantity of residual hydrogen is approximately 2.6.10¹⁶ H/cm². In accordance with the invention, the film of InP is then implanted with boron ions at an energy of 230 keV and a dose of 3.10¹⁵ B/cm². The peak of the boron atoms is then situated at 515 nm under the fractured surface. Annealing at 400° C. for one hour makes it possible to trap up to 1.3.10¹⁶ H/cm² between the surface and the boron peak. The film of InP is next polished by mechanochemical polishing to the required final thickness of 380 nm. High-temperature annealing can then be applied in order to consolidate the bonding and cure any defects related to the implantation.

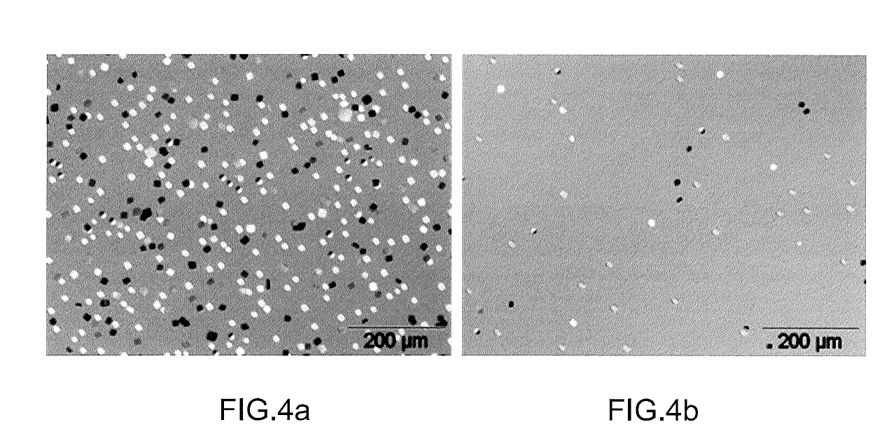

In FIG. 5, the curve G represents the hydrogen [H] concentration as a function of the depth Pf in the transferred film directly after fracture, while the curve H represents the hydrogen concentration after formation of the hydrogen trapping layer by the implantation of boron. The curve I for its part represents the hydrogen concentration after formation of the hydrogen trapping layer by boron implantation and application of annealing at 400° C. for one hour. This curve I shows the retention of a dose of 1.3.10¹⁶ H/cm² at the 350 nm depth. Finally, the curve J for its part represents the hydrogen concentration after post-fracture application of annealing at 400° C. for one hour, in the absence of any formation of a hydrogen trapping layer. It is found that the hydrogen has entirely diffused, to a great extent to the bonding interface, giving rise to the formation of surface blisters.

### EXAMPLE 2

A Zn doped GaAs donor substrate (100) is implanted with H2⁺ ions at an energy of 240 keV, a dose of 3.4.10¹⁶/cm² and at a temperature of 275° C. This donor substrate is bonded to an InP receiver substrate by direct bonding, and fracture is caused by annealing at 200° C. for 2 hours. The GaAs film transferred has a thickness of 500 nm, and its H-rich zone extends from the surface to a depth of 400 nm.

The GaAs receiver substrate is then implanted with B ions at an energy of 100 keV and a dose of 3.10¹⁵/cm². The peak of the B atoms is then situated at approximately 250 nm under the fractured surface. Annealing at 600° C. for one hour is carried out in order to trap the residual hydrogen in the GaAs film transferred. The GaAs film is next polished to approximately 250 nm in order to obtain the required final thickness of 250 nm.

1. A method for treating a thin film transferred from a donor substrate to a receiver substrate by fracture at a zone of the donor substrate weakened by hydrogen ion implantation, the method comprising:
directly after the fracture, forming a hydrogen trapping layer in a residual-defect region of the transferred thin film, and
subsequently thinning the transferred thin film in order to eliminate the residual-defect region,
wherein the thinning extends at least from a surface of the transferred thin film to the hydrogen trapping layer.

2. The method according to claim 1, wherein the forming of the hydrogen trapping layer comprises introducing at least one hydrogen trapping substance selected from the group consisting of Li, B, C, N, F, Si, P and S into the transferred thin film.

3. The method according to claim 2, wherein the introducing of the hydrogen trapping substance into the transferred thin film is carried out by ion implantation.

4. The method according to of claim 1, further comprising,
after the forming and before the thinning, applying a heat treatment to the transferred thin film.

5. The method according to claim 4, wherein the heat treatment is carried out at a temperature of between 300° C. and 700° C.

6. The method according to claim 4, wherein the heat treatment is carried out in an atmosphere devoid of hydrogen.

7. The method according to claim 1, wherein the thinning comprises removing the hydrogen trapping layer.

8. The method according to claim 7, wherein the thinning comprises a mechanochemical polishing.

9. The method according to claim 1, wherein the transferred thin film is produced from one or more materials selected from the group consisting of InP, GaAs, and an alloy based on In, P, Ga, and As.
